(19) United States
(12) Patent Application Publication
(10) Pub. No.: US 2002/0117680 A1
(43) Pub. Date: Aug. 29, 2002

(54) Semiconductor device and method of manufacture of the semiconductor device

(76) Inventors: Keiichi Yabusaki, Tokyo (JP); Michio Ohkubo, Tokyo (JP)

Correspondence Address: COUDERT BROTHERS LLP, 600 Beach Street, Third Floor, San Francisco, CA, 94109, US

(21) Appl. No.: 10/003,933

(22) Filed: Oct. 23, 2001

(30) Foreign Application Priority Data
Dec. 27, 2000 (JP) 2000-399423

(51) Int. Cl. H01L 21/00; H01L 33/00; H01S 5/00

(52) U.S. Cl. 257/101; 438/22; 438/37; 438/936; 257/103; 372/45

(57) ABSTRACT

The semiconductor laser device has a lower clad layer, an active layer, an upper clad layer, a forward mesa forming layer, a contact layer and an insulating film, sequentially formed on the semiconductor substrate. The upper clad layer, the forward mesa forming layer, the contact layer and the insulating film form a ridge. The etching speed of the forward mesa forming layer is higher than that of the upper clad layer and lower than that of the contact layer. Because of such etching speeds, the ridge having a forward mesa structure is formed.

### FIELD OF THE INVENTION

The present invention relates to semiconductor devices having ridge structure, such as the ridge-type semiconductor laser devices. The ridge structure may be formed on top of a surface of a substrate, or within a surface of a substrate, as in the case of double channel semiconductor devices, such as Double Channel Planar Buried Heterostructures.

### BACKGROUND OF THE INVENTION

Conventionally, semiconductor devices having desired electric circuitry or desired electric elements have been formed by forming a multi-layer film structure on a semiconductor substrate and then performing etching or the like.

FIG. 7 is a sectional view of a conventional semiconductor laser device which is an example of a semiconductor device. This semiconductor laser device has the ridge 12′ in a stripe shape, and light and electric current are confined by this ridge 12′. As a result, this semiconductor laser device exhibits good lasing ability with a simple structure, and is used in various fields such as optical communication, optical recording and measurements, for light-emitting devices and optical fiber amplifier excitation apparatus.

This semiconductor laser device has a lower clad layer 3, an active layer 4, an upper clad layer 5, a contact layer 9 and an insulating film 6 sequentially formed on the upper face of semiconductor substrate 2. A part of the upper clad layer 5, contact layer 9 and the insulating film 6 together form ridge 12′. In addition, a negative electrode 1 is formed on the lower face of the semiconductor substrate 2, and a positive electrode 7 is formed on the upper face of the semiconductor laser device.

This conventional semiconductor laser device is manufactured with a method that is shown in FIG. 8A to FIG. 8C and FIG. 9A to 9C. As shown in FIG. 8A, the lower clad layer 3, active layer 4, upper clad layer 5 and the contact layer 9 are sequentially formed on one surface of the semiconductor substrate 2. Then, the resist 10 is applied to form a film on the contact layer 9.

Thereafter, as shown in FIG. 8B, the contact layer 9 and the upper clad layer 5 are etched by to thereby form the ridge 12′ having the same width as that of the resist 10. Subsequently, as shown in FIG. 8C, the resist 10 is removed, and the insulating film 6 is formed on the exposed surfaces of the upper clad layer 5 and the contact layer 9. Thus, the insulating film 6 completely covers the ridge 12′.

Subsequently, as shown in FIG. 9A, the resist 11 is applied on the insulating film 6. This resist 11 is applied in such a manner that it covers the ridge 12′. Although not shown in the drawing, another resist is formed above the resist 11 thereby making the surface above the ridge 12′ and its periphery flat. Thereafter, as shown in FIG. 9B, photolithography and oxygen plasma ashing processing are performed thereto, to remove the resist 11 on the upper face of the ridge 12′ and the peripheral portion thereof, up to the height of the insulating film 6 of the ridge 12′, to thereby expose the insulating film 6 on the upper face of the ridge 12′.

Subsequently, as shown in FIG. 9C, the insulating film 6 on the upper face of the ridge 12′ is removed by plasma etching processing, to thereby expose the contact layer 9. Then, the resist 11 is completely removed, and the positive electrode 7 (see FIG. 7) is deposited on the entire upper face including the side of the ridge 12′. Finally, the lower face of the substrate is milled and polished to reduce the thickness of the substrate, and the negative electrode 1 (see FIG. 7) is deposited on the lower face of the semiconductor substrate 2. Thus, the conventional ridge-type semiconductor laser device is obtained.

The positive electrode 7 and the negative electrode 1 are each generally formed using a dry deposition process, a plating process, and several photolithography processing steps (resist coating, exposure UV light, resist development, and resist stripping) to define masks for dry deposition process and the plating process. An ionic solution is generally used for developing an image in the resist, and an organic solvent is generally used to strip the photo-resist, although an aqueous alkaline solution (which is ionic) can sometimes be used for stripping, depending upon the composition of the resist. The plating bath used in the plating process is generally an ionic solution.

In the conventional semiconductor laser device, an erosion of the contact layer 9 often occurs when the positive electrode 7 and negative electrode 1 are formed. When the contact layer 9 is eroded, the current channel of the obtained semiconductor laser device becomes narrow and thereby the electric resistance increases. As a result, there is a drawback that the optical output of the semiconductor laser device decreases. If the erosion is severe, most of the contact layer 9 and the upper clad layer 5 are affected, thereby the optical output further decreases.

The present invention is directed to understanding the causes of this erosion, and to minimizing, and hopefully substantially preventing, the occurrence of the erosion.

### SUMMARY OF THE INVENTION

In making their invention, the inventors have recognized that the erosion is caused by cracks within the top positive electrode layer, and the subsequent filling of these cracks with ionic solutions and/or organic solvents from the photo-lithographic process and/or plating process, with the ionic solutions and/or the organic solvents causing the erosion. Furthermore, the inventors believe that the cracks are caused by stresses within the ridge, and that these stresses result from the exposure of the ridge to various temperatures during the various manufacturing processes.

It is an object of the present invention to provide a semiconductor device which reduces these stresses, and which does not have cracks in the positive electrode or erosion of the contact layer.

It is another object of this invention to provide a method by which such semiconductor devices can be manufactured easily and efficiently.

According to the present invention, the ridge is formed by a first semiconductor layer, a second semiconductor layer, and a third semiconductor layer sequentially from bottom to top, with at least two of the layers having different compositions or properties. When etched by a desired etchant, the first semiconductor layer is etched at a first etching speed, the second semiconductor layer is etched at a second etching speed, and the third semiconductor layer is etched at a third etching speed. The second etching speed is higher than the first etching speed and slower than the third etching speed.

Other objects and features of this invention will become apparent from the following description with reference to the accompanying drawings.

### BRIEF DESCRIPTION OF THE DRAWINGS

FIG. 1 is a sectional view of a semiconductor laser device, being one embodiment of the present invention;

FIG. 2A to FIG. 2C are sectional views showing the manufacturing process of the semiconductor laser device shown in FIG. 1 according to the present invention;

FIG. 3A to FIG. 3C are sectional views showing continuation of the manufacturing process of the semiconductor laser device shown in FIG. 1 according to the present invention;

FIG. 4 is an enlarged sectional view of a ridge portion of an exemplary semiconductor laser device according to the present invention;

FIG. 5 is a diagram showing the distribution of aluminum in the ridge portion according to one embodiment of the present invention;

FIG. 6 is a diagram showing a case where the composition of aluminum in a forward mesa forming layer changes stepwise according to another embodiment of the present invention;

FIG. 7 is a sectional view of a semiconductor laser device which is an example of a conventional semiconductor device;

FIG. 8A to FIG. 8C are sectional views showing the manufacturing process of the semiconductor laser device shown in FIG. 7; and

FIG. 9A to FIG. 9C are sectional views showing continuation of the manufacturing process of the semiconductor laser device shown in FIG. 7.

### DETAILED DESCRIPTION OF THE EMBODIMENTS

Embodiments of the semiconductor device and the manufacturing methods thereof according to the present invention will be explained below in detail, with reference to the accompanying drawings.

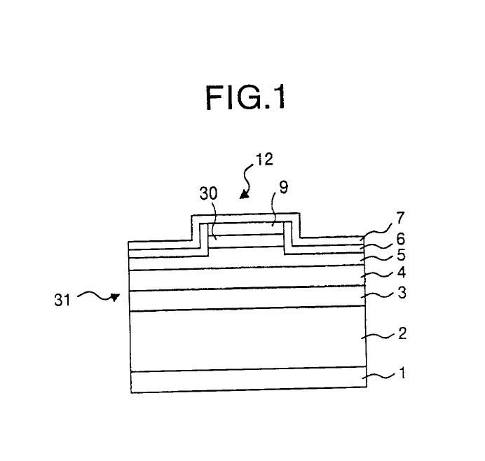

FIG. 1 is a sectional view of an exemplary semiconductor laser device according to one embodiment of the present invention. The multi-layer film substrate 31 forming the semiconductor laser device has a lower clad layer 3, an active layer 4, an upper clad layer 5, a forward mesa forming layer 30, a contact layer 9 and an insulating film 6 formed on the upper face of a semiconductor substrate 2. The upper clad layer 5, forward mesa forming layer 30, contact layer 9 and the insulating film 6 together form a ridge 12. Next, a negative electrode 1 is formed on the lower face of the semiconductor substrate 2, and a positive electrode 7 is formed on the upper face of the multi-layer film substrate 31.

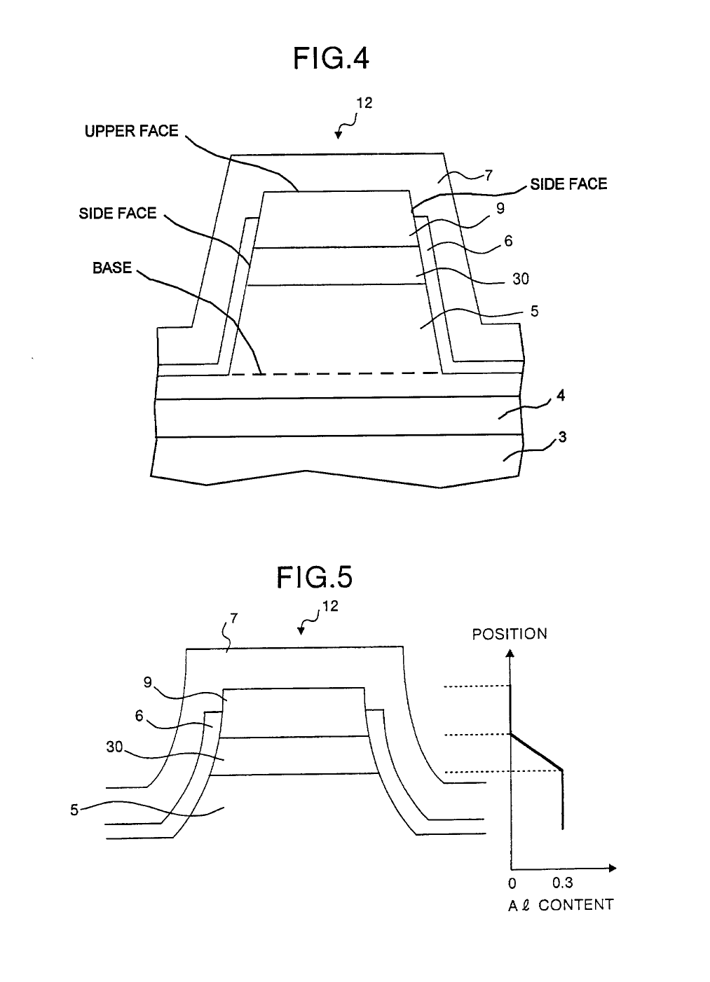

FIG. 4 is an enlarged sectional view of the ridge portion of the exemplary semiconductor laser device according to the present invention. As shown in the figure, the ridge comprises a base, an upper face located above the base, and side faces located between the ridge's upper face and the base. The base is attached to the composite substrate formed by substrate 2, layer 3, layer 4, and the lower portion of layer 5. In general, the ridge according to the present invention may be attached to homogeneous substrate (such as substrate 2) or a composite substrate which comprises many layers, such as shown in FIG. 4. These definitions of base, side face, and upper face of the ridge apply to the ridge as shown in FIGS. 1, 2B-2C, 3A-3C, and 5-6. Upper clad layer 5 is a first semiconductor layer of the ridge and is located closer to the base than the upper face of the ridge. Forward mesa forming layer 30 is a second semiconductor layer of the ridge and is located above layer 5 and below the upper face. Layer 30 has a bottom surface located near layer 5 and a top surface located near layer 9. Contact layer 9 is a third semiconductor layer of the ridge and is located above layer 30 and below the upper face.

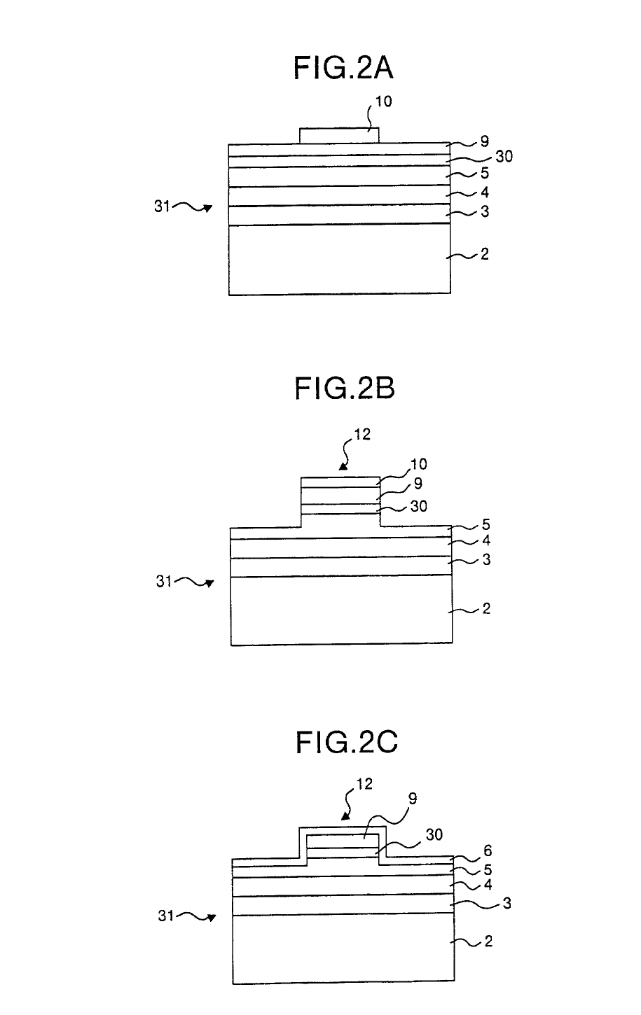

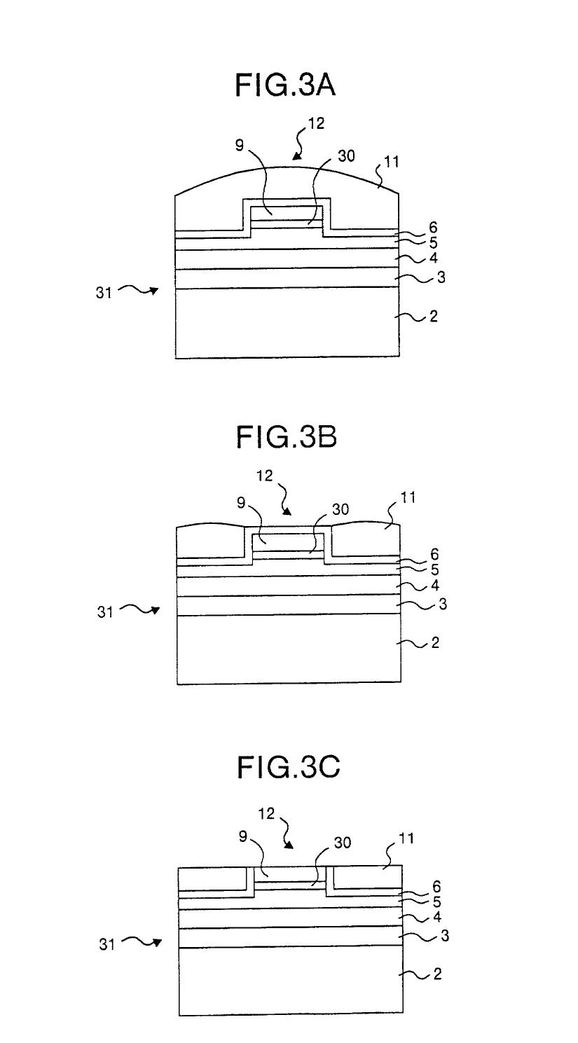

This semiconductor laser device is manufactured with a process that will be explained with reference to FIG. 2A to FIG. 2C and FIG. 3A to FIG. 3C. As shown in FIG. 2A, the lower clad layer 3 having a composition of n-type AlGaAs, the active layer 4, the upper clad layer 5 having a composition of p-type Alₓ₁Ga₁₋ₓ₁As, the forward mesa forming layer 30 having a composition of p-type Alₓ₂Ga₁₋₂As, and the contact layer 9 having a composition of p-type GaAs are sequentially formed on the one surface of the semiconductor substrate 2 having a composition of n-type GaAs. X1 is the Al—Ga stoichiometric parameter of upper clad layer, and x2 is the Al—Ga stoichiometric parameter of forward mesa forming layer 30. Stoichiometric parameter X1 is substantially constant, and typically ranges between 0.2 and 0.5, and is preferably between 0.25 and 0.35. In the composition of the forward mesa forming layer 30, stoichiometric parameter x2 is variable which decreases monotonically in value from the bottom surface of layer 30 (which is adjacent to upper clad layer 5) toward the top surface of layer 30 (which is adjacent to contact layer 9). X2 may decrease continuously, or in one or more steps. (As is known in the art, the term “monotonically” means that the value moves in only one direction: (1) the same level or increasing to a higher level, or (2) the same level or decreasing to a lower level.) The various layers may be formed using the thin-film epitaxial growth method such as the MOCVD method or MBE method.

It may be appreciated that instead of comprising GaAs, contact layer 9 may comprise Alₓ₃Ga₁₋₃As, where x3 is relatively small (such as x3<0.05). In this case, Stoichiometric parameter x3 is preferably substantially constant and substantially less than or equal to the lowest value of the stoichiometric parameter x2 of layer 30.

A resist 10 is then applied to form a film on the contact layer 9.

Thereafter, as shown in FIG. 2B, the contact layer 9, the forward mesa forming layer 30 and the upper clad layer 5 are etched by wet etching processing using citric acid type solution to thereby form the ridge 12 having substantially the same width as that of the resist 10. Subsequently, as shown in FIG. 2C, the resist 10 on the upper face of the multi-layer film substrate 31 is removed by dissolving it using a stripping solution, and any residual of the resist 10 is then completely removed by the oxygen plasma ashing processing. Then, the insulating film 6 is formed on the upper face of the multi-layer film substrate 31, using the plasma CVD method or the like. This insulating film 6 is formed on the upper face of the upper clad layer 5, on the upper face of the ridge 12 and on the side of the ridge 12. The insulating film 6 may be a silicon nitride film.

Subsequently, as shown in FIG. 3A, the resist 11 is formed above the ridge 12 in such a manner that the resists rises above the ridge 12 in height. Spin coat or the like is used for application of the resist 11.

Subsequently, as shown in FIG. 3B, a portion of the resist 11 is removed by the photolithography and oxygen plasma etching processing. The etching process is controlled in such a manner that the etching stops when the insulating film 6 above the ridge 12 gets exposed.

Thereafter, for example, as shown in FIG. 3C, FREON-gas plasma etching processing is performed to remove the insulating film 6 on the upper face of the ridge 12. The etching process is controlled in such a manner that the etching stops when the contact layer 9 is exposed. The thickness of the resist 11 at this stage is from 1.6 μm to 1.8 μm, as measured from the top of layer 6 (in the area away from the ridge), and is from 1.8 μm to 2 μm, as measured from the top of layer 5 (in the area away from the ridge). Therefore, the resist 11 serves as a protective cover with respect to the insulating film 6 in a portion other than the ridge 12, when etching the insulating film 6 on the upper face of the ridge 12.

The resist 11 is then dissolved and removed using a stripping solution, and the oxygen plasma ashing processing is applied to thereby remove the remaining resist 11. As the stripping solution, one containing aromatic hydrocarbon, phenol and alkyl benzene sulfonate at a ratio of 6:2:2 may be used.

Next, the positive electrode 7 (see FIG. 1) is formed on the exposed face of the contact layer 9 and on the insulating film 6 using a dry deposition process, a plating process, and several photolithography processing steps, as previously described above for the prior art device. The deposited conductive layer for electrode 7 generally comprises a first sublayer of an adhesive metal (such as titanium—Ti) with a thickness of at least 75 nm, and a second sublayer of a gold-diffusion barrier layer (such at platinum—Pt) with a thickness of at least 75 nm. In preferred embodiments, both the adhesion sublayer and the barrier sublayer preferably comprise substantially no gold (Au), each comprising not more than 5% of gold by weight, and preferably not more than 0.5% by weight. After electrode 7 is formed, a thick gold layer is plated over electrode 7 through a patterned plating mask, as previously described. The ionic solutions and solvents which contact the metal electrode 7 after it is formed have the potential of eroding portions of the ridge if they infiltrate through the electrode 7. The forward mesa shape of the ridge according to the present invention, however, reduces the stresses which cause cracks to develop in electrode 7, and thus reduces the occurrence of the infiltration and the occurrence of the erosion. Next, the lower face of the semiconductor substrate 2 is milled and polished and, then the negative electrode 1 is formed thereon. Similar steps are used to form the negative electrode 1, including exposure to one or more ionic developer solutions and one or more organic solvents. The milling process used to thin the substrate also uses organic solvents, and may sometimes use ionic developer solutions.

The dry deposition process may be performed by a vapor deposition apparatus or a sputtering apparatus, or the like, all of which are generically referred to as dry deposition apparatuses herein. The dry deposition apparatus comprises a deposition axis along which deposition material flows in low pressure gaseous environment (e.g., near vacuum), and a holder for holding a substrate within the deposition field of the apparatus. In preferred practice of the present invention, the holder is capable of revolving about a center axis of the holder, this center axis being substantially parallel to a normal vector of the top surface of the substrate which is held by the holder. The holder is oriented within deposition field such that its center axis is preferably inclined with respect to the deposition axis (i.e., the center axis and the deposition axis form a non-zero acute angle.) This configuration enables the thickness of the electrode on the upper face and the thickness on the side face of the ridge 12 to be made substantially the same.

The multi-layer film substrate 31 formed by the above-described process is cleaved, assembled as a module, and mounted to thereby complete the semiconductor laser device.

FIG. 4 is an enlarged sectional view of the ridge portion of the semiconductor laser device according to the present invention. As can be seen clearly, the width of the ridge 12 increases gradually from the upper face of the contact layer 9 towards the upper clad layer 5. That is, the side of the ridge 12 forms a forward mesa form. Therefore, stress applied on the ridge 12 can be dispersed very smoothly and effectively. As a result, erosion of the contact layer 9 or formation of cracks at the boundary between the positive electrode 7 and the insulating film 6 are substantially reduced, and preferably prevented. FIG. 4 shows that the side faces of the semiconductor laser device are straight, however, the side faces may be curved so as to have concave surfaces, as shown in FIG. 5.

FIG. 5 is a diagram showing the distribution of aluminum (Al) in the composition of the ridge 12. The contact layer 9 is composed of p-type GaAs, and has a thickness of 400 nm. The upper clad layer 5 is composed of p-type Al_{0.3}Ga_{0.7}As (x1=0.3). The forward mesa forming layer 30 is a p-type AlGaAs layer having a thickness of 30 nm, wherein the composition of aluminum is 0.3 (x2=0.3) near the upper clad layer 5 and 0 (x2=0) near the contact layer 9. The composition of aluminum in the forward mesa forming layer 30 (x2) decreases monotonically and substantially continuously from the upper clad layer 5 towards the contact layer 9. When the content of aluminum is more, the etching speed decreases. That is, the forward mesa forming layer 30 is etched faster near the contact layer 9 than near the upper clad layer 5.

In general, forward mesa forming layer 30 may have a thickness in the range of 5 nm to 1000 nm, and more preferably in the range of 25 nm to 100 nm, and most preferably in the range of 25 nm to 35 nm. In preferred embodiments, the thickness of layers 5 and 9 are greater than the thickness of forward mesa forming layer 30.

The positive electrode 7 has substantially the same thickness on the upper face and on the side face of the ridge 12. In other words, 200 nm thick positive electrode 7 is formed on the sides faces and the upper face of the ridge 12. This thickness is sufficient enough to prevent formation of cracks or at the boundary between the positive electrode 7 and the insulating film 6, and erosion of the contact layer 9. In general, the thickness of electrode layer 7 is equal to or greater than 100 nm, and more preferably equal to or greater than 150 nm, and most preferably equal to or greater than 200 nm.

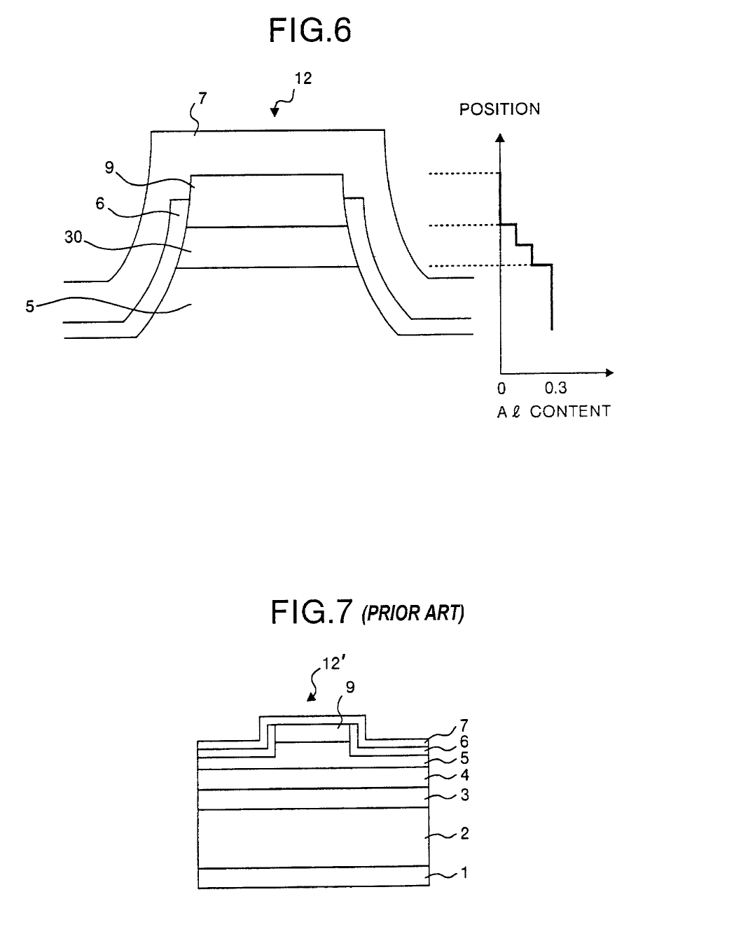

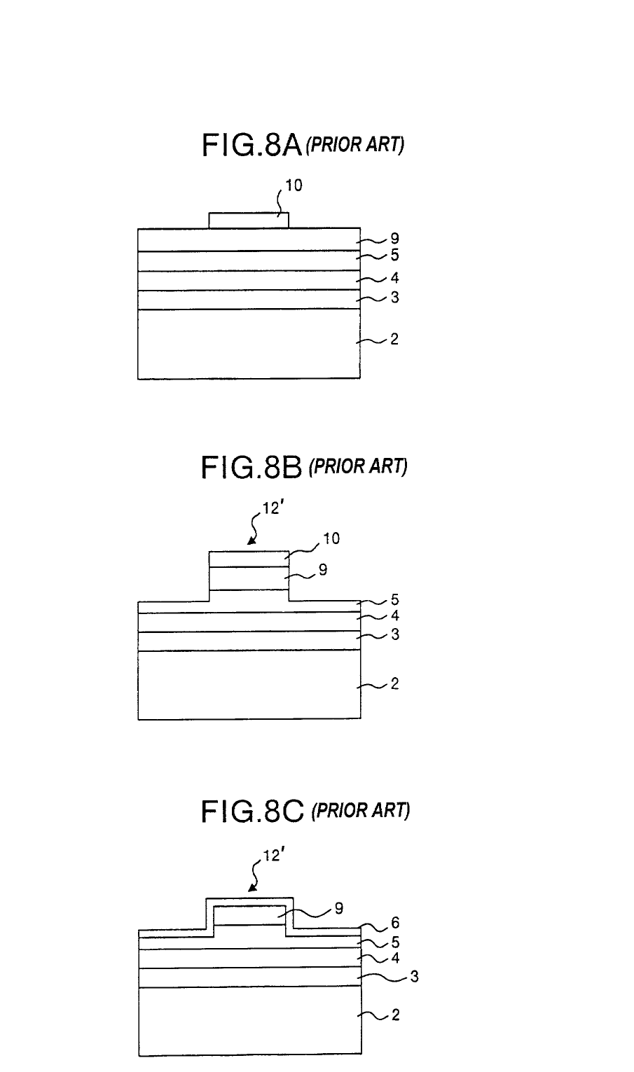

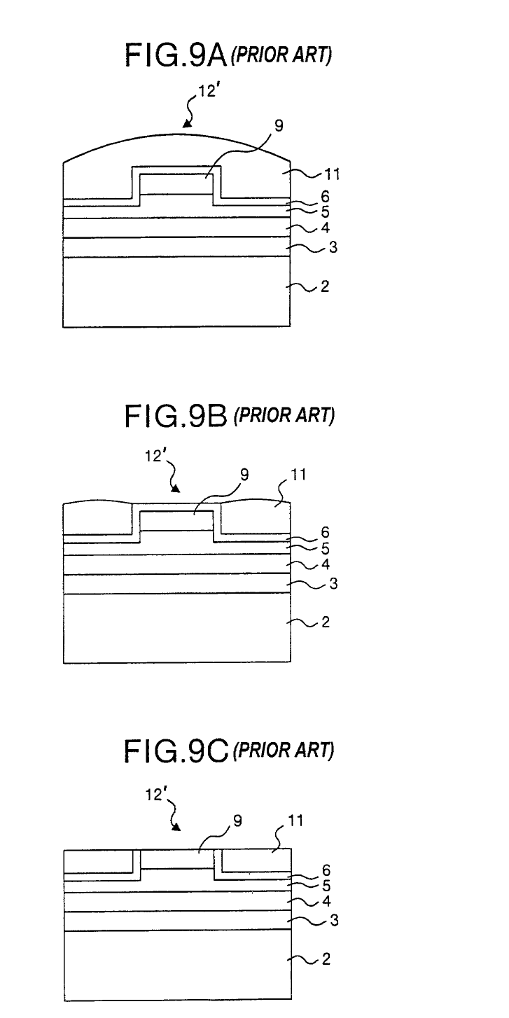

The composition of the forward mesa forming layer 30 may be changed stepwise, e.g., in one or more steps. FIG. 6 is a diagram showing an embodiment in which the composition of aluminum in the forward mesa forming layer is changed stepwise (two steps). The contact layer 9 is composed of p-type GaAs and has a thickness of about 400 nm. The upper clad layer 5 is composed of p-type Al_{0.3}Ga_{0.7}As. The forward mesa forming layer 30 is a p-type AlGaAs layer having a thickness of 30 nm, wherein the composition of aluminum changes stepwise. In other words, in the forward mesa forming layer 30, the composition of aluminum changes from about 0.3 to about 0.2 near the upper clad layer 5, changes from about 0.2 to 0.1 in the middle of layer 30, and it is about 0.1 near the contact layer 9.

When the composition of the forward mesa forming layer 30 is changed stepwise, the side of the ridge 12 becomes the forward mesa form. The positive electrode 7 preferably has the same thickness on the upper face and on the side face of the ridge 12.

Thus, the semiconductor laser device according to this embodiment has the forward mesa forming layer 30 between the upper clad layer 5 and the contact layer 9 in the ridge section. The aluminum content of the forward mesa forming layer 30 is less near the contact layer 9 and more near the upper clad layer 5. Since the aluminum content is less near the contact layer 9 the forward mesa forming layer 30 is etched faster near the contact layer 9 than near the upper clad layer 5, thereby forming a ridge having a forward mesa form.

Because of the formation of the ridge having the forward mesa form, no cracks or distortions are generated. As a result, there is no erosion of the contact layer 9 and there is no loss of light output.

It has been mentioned above that the ridge 12 is formed by wet etching. However, the ridge 12 may be formed by dry etching.

Furthermore, a semiconductor laser device having a simple ridge stripe structure has been taken as an example in the above explanation. However, the present invention may be applied to a semiconductor laser device having a double channel structure. In the first case, the ridge 12 is formed on top of the substrate's top surface. In the second case, the ridge is formed into the top surface of the substrate by forming one or more grooves in the substrate at the top surface to define the two or more sides of the ridge. In this second case, two grooves are generally used, one on either side of the ridge, but one may use a single continuous groove which encircles the ridge.

Furthermore, a ridge-type semiconductor laser device has been taken as an example of semiconductor device in the above explanation. However, the present invention may be applied to, for example, a ridge guiding semiconductor photodetector.

Furthermore, a semiconductor laser device has been taken as an example in the above explanation. However, the present invention can be widely applied to a general semiconductor device in which a multi-layer film is simply formed into a ridge shape by etching processing.

As explained above, according to the present invention, the ridge of the semiconductor device is formed from the first, second, and the third semiconductor layers sequentially from bottom to top. The etching speed of the second semiconductor layer is higher than that of the first semiconductor layer and slower than that of the third semiconductor layer. Therefore, precise machining can be performed by etching, cracks or erosion due to an abnormal shape can be prevented, and high yield can be realized.

Furthermore, the second semiconductor layer is formed in such a manner that the second etching speed is variable and it increases monotonically from near the boundary between the first semiconductor layer to the boundary between the third semiconductor layer, preferably in either a continuous manner or a stepwise manner. Therefore, fine machining by etching can be further performed with higher precision.

Furthermore, stoichiometric composition ratio of the second semiconductor layer is sequentially changed to thereby make the second etching speed variable. Therefore a change in the etching speed can be easily realized, machining by etching can be performed precisely, cracks or invasion due to an abnormal shape can be prevented from occurring, and high yield can be realized.

Furthermore, the first semiconductor layer has a composition Alₓ₁Ga₁₋ₓ₁As where x1 is substantially constant, the third semiconductor layer has a composition GaAs, and the second semiconductor layer has a composition Alₓ₂Ga₁₋₂As wherein x2 is a variable. This construction reduces, and preferably prevents, the occurrence of a reverse mesa form by creating a forward mesa form. In general, a reverse mesa slope can create stress within the ridge, which in turn may cause cracks in electrode layer 7. (In the inventors' co-pending patent application Ser. No. ______, they propose another invention for addressing cracks that may occur in reverse mesa ridges.) Furthermore, an electrode layer is provided above the third semiconductor layer and covering at least the side of the ridge portion in the longitudinal direction, wherein the thickness of the electrode layer is equal to or greater than 100 nm, more preferably equal to or greater than 150 nm, and most preferably equal to or greater than 200 nm. Therefore, occurrence of cracks caused by the stress applied on the electrode layer can be prevented, and invasion to the inside of the covering portion can be prevented.

The semiconductor device according to the present invention can be effectively and easily formed using the semiconductor device manufacturing method according to the present invention.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device having a multiple layered ridge, said ridge including:
a first semiconductor layer forming the bottom part of said ridge, said first semiconductor layer having a first etching speed in a first etchant;
a second semiconductor layer disposed above said first semiconductor layer, said second semiconductor layer having a second etching speed in the first etchant; and
a third semiconductor layer disposed above said second semiconductor layer and forming the top part of said ridge, said third semiconductor layer having a third etching speed in the first etchant, wherein the second etching speed is higher than the first etching speed and slower than the third etching speed.

2. The semiconductor device according to claim 1, wherein said second semiconductor layer has a bottom surface located near the first semiconductor layer and top surface located near the third semiconductor layer, and wherein the second etching speed is variable and increases monotonically from the layer's bottom surface to the layer's top surface.

3. The semiconductor device according to claim 2, wherein the second etching speed increases continuously from the bottom surface of said second semiconductor layer to the top surface of said second semiconductor layer.

4. The semiconductor device according to claim 1, wherein said second semiconductor layer has a bottom surface located near the first semiconductor layer and top surface located near the third semiconductor layer, and wherein the second etching speed is variable and it increases in one or more steps from the layer's bottom surface to the layer's top surface.

5. The semiconductor device according to claim 2, wherein the second semiconductor layer comprises two or more atomic elements, and wherein the stoichiometric ratio of the atomic elements of said second semiconductor layer is changed to thereby make the second etching speed variable.

6. The semiconductor device according to claim 1, wherein said first semiconductor layer comprises a composition of Alₓ₁Ga₁₋ₓ₁As where the stoichiometric parameter x1 is substantially constant, wherein said third semiconductor layer comprises a composition of GaAs, and wherein said second semiconductor layer comprises a composition of Alₓ₂Ga₁₋₂As where the stoichiometric parameter x2 is a variable.

7. The semiconductor device according to claim 6, wherein the stoichiometric parameter x1 for the first semiconductor layer is in a range of 0.2 to 0.5.

8. The semiconductor device according to claim 1 further comprising an electrode layer disposed above said third semiconductor layer and covering at least a side of said ridge portion in the longitudinal direction, wherein the thickness of said electrode layer is equal to or more than 100 nm.

9. The semiconductor device according to claim 1 wherein said second semiconductor layer has a thickness in a range of 5 nm to 1000 nm.

10. The semiconductor device according to claim 1 wherein said second semiconductor layer has a thickness in a range of 25 nm to 100 nm.

11. The semiconductor device according to claim 1 wherein said second semiconductor layer has a thickness in a range of 25 nm to 35 nm.

12. The semiconductor device according to claim 11 wherein the thickness of said first semiconductor layer is greater than the thickness of said second semiconductor layer, and wherein the thickness of the third semiconductor layer is greater than the thickness of the second semiconductor layer.

13. A method of manufacturing a semiconductor device having a multiple layered ridge, the method comprising the steps of:
forming a first semiconductor layer as a bottom part of the ridge, said first semiconductor layer being etched at a first etching speed by a first etchant;
forming a second semiconductor layer above said first semiconductor layer, said second semiconductor layer being etched at a second etching speed by the first etchant; and
forming a third semiconductor layer above said second semiconductor layer as a top part of the ridge, said third semiconductor layer being etched at a third etching speed by the first etchant,
wherein the second etching speed is higher than the first etching speed and slower than the third etching speed.

14. The method according to claim 13, wherein said second semiconductor layer has a bottom surface located near said first semiconductor layer and top surface located near said third semiconductor layer, and wherein said second semiconductor layer is formed with a composition that causes the second etching speed to be variable and to increase monotonically from the layer's bottom surface to the layer's top surface.

15. The semiconductor device according to claim 14, wherein the second etching speed increases continuously from the bottom surface of said second semiconductor layer to the top surface of said second semiconductor layer.

16. The method according to claim 13, wherein said second semiconductor layer has a bottom surface located near said first semiconductor layer and top surface located near said third semiconductor layer, and wherein said second semiconductor layer is formed with a composition that causes the second etching speed to be variable and to increase in one or more steps from the layer's bottom surface to the layer's top surface.

17. The method according to claim 14, wherein the second semiconductor layer comprises two or more atomic elements, and wherein the stoichiometric ratio of the elements of said second semiconductor layer is sequentially changed to thereby make the second etching speed variable.

18. The method according to claim 13, wherein said first semiconductor layer comprises a composition Alₓ₂Ga₁₋ₓ₁As where x1 is substantially constant, wherein said third semiconductor layer comprises a composition of GaAs, and wherein said second semiconductor layer comprises a composition of Alₓ₂Ga₁₋ₓ₂As where x2 is a variable.

19. The method according to claim 13 further comprising a step of forming an electrode layer above said third semiconductor layer and covering at least the side of said ridge portion in the longitudinal direction, wherein the thickness of said electrode layer is equal to or more than 100 nm.

20. The method according to claim 13 further comprising a step of forming an electrode layer above said third semiconductor layer and covering at least the side of said ridge portion in the longitudinal direction, wherein the thickness of said electrode layer is equal to or more than 150 nm.

21. The method according to claim 13 further comprising a step of forming an electrode layer above said third semiconductor layer and covering at least the side of said ridge portion in the longitudinal direction, wherein the thickness of said electrode layer is equal to or more than 200 nm.

22. A semiconductor device having a multiple layered ridge formed at a first surface of a substrate, said ridge including:
a base attached to the substrate, an upper face located above the base, and at least a first side face located between the ridge's upper face and the base;
a first semiconductor layer located closer to the base than the upper face of the ridge, said first semiconductor layer having a composition of Alₓ₁Ga₁₋ₓ₂As where the stoichiometric parameter x1 is substantially constant;
a second semiconductor layer located above said first semiconductor layer and below said upper face, said second semiconductor layer having a composition of Alₓ₂Ga₁₋ₓ₂As where the stoichiometric parameter x2 is variable with a range of values which are less than or equal to X1; and
a third semiconductor layer located above said second semiconductor layer and below said upper face, said third semiconductor layer having a composition of Alₓ₃Ga₁₋ₓ₃As where the stoichiometric parameter x3 is substantially constant and substantially less than or equal to the lowest value of the stoichiometric parameter x2; and
wherein said second semiconductor layer has a bottom surface located near the first semiconductor layer and top surface located near the third semiconductor layer,
wherein the stoichiometric parameter X2 decreases monotonically from the bottom surface of the second semiconductor layer to the top surface of the second semiconductor layer, and wherein said first side face comprises a forward mesa surface.

23. The semiconductor device according to claim 22, wherein said second semiconductor layer has a bottom surface located near the first semiconductor layer and top surface located near the third semiconductor layer, and wherein the stoichiometric parameter x2 decreases monotonically from the layer's bottom surface to the layer's top surface.

24. The semiconductor device according to claim 23, wherein the stoichiometric parameter x2 decreases continuously from the bottom surface of said second semiconductor layer to the top surface of said second semiconductor layer.

25. The semiconductor device according to claim 22, wherein said second semiconductor layer has a bottom surface located near the first semiconductor layer and top surface located near the third semiconductor layer, and wherein the stoichiometric parameter x2 decreases in one or more steps from the layer's bottom surface to the layer's top surface.

26. The semiconductor device according to claim 22, wherein said first side face comprises a concave surface.

27. The semiconductor device according to claim 22, wherein the stoichiometric parameter x1 for the first semiconductor layer is in a range of 0.2 to 0.5.

28. The semiconductor device according to claim 22, wherein the stoichiometric parameter x1 for the first semiconductor layer is in a range of 0.25 to 0.35.

29. The semiconductor device according to claim 22, wherein the stoichiometric parameter x1 for the first semiconductor layer is in a range of 0.2 to 0.5, and wherein the stoichiometric parameter x3 for the third semiconductor layer is less than or equal to 0.05.

30. The semiconductor device according to claim 22, wherein the third semiconductor layer comprises GaAs with the stoichiometric parameter x3 being substantially equal to zero.

31. The semiconductor device according to claim 22 wherein said second semiconductor layer has a thickness in a range of 5 nm to 1000 nm.

32. The semiconductor device according to claim 22 wherein said second semiconductor layer has a thickness in a range of 25 nm to 100 nm.

33. The semiconductor device according to claim 22 wherein said second semiconductor layer has a thickness in a range of 25 nm to 35 nm.

34. The semiconductor device according to claim 32 wherein the thickness of said first semiconductor layer is greater than the thickness of said second semiconductor layer, and wherein the thickness of the third semiconductor layer is greater than the thickness of the second semiconductor layer.

35. The semiconductor device according to claim 22 further comprising an electrode layer disposed above said third semiconductor layer and covering at least the side of said ridge portion in the longitudinal direction, wherein the thickness of said electrode layer is equal to or more than 100 nm.

36. The semiconductor device according to claim 22 further comprising an electrode layer disposed above said third semiconductor layer and covering at least the side of said ridge portion in the longitudinal direction, wherein the thickness of said electrode layer is equal to or more than 150 nm.

37. The semiconductor device according to claim 22 further comprising an electrode layer disposed above said third semiconductor layer and covering at least the side of said ridge portion in the longitudinal direction, wherein the thickness of said electrode layer is equal to or more than 200 nm.

38. A method of manufacturing a semiconductor device having a multiple layered ridge, the ridge having a base attached to a substrate, an upper face located above the base, and at least a first side face located between the ridge's upper face and the base, the method comprising the steps of:
(a) forming a first semiconductor layer located closer to the base than the upper face of the ridge, the first semiconductor layer having a composition of Alₓ₁Ga₁₋ₓ₁As where the stoichiometric parameter x1 is substantially constant;
(b) forming a second semiconductor layer over the first semiconductor layer and located below the upper face, the second semiconductor layer having a bottom surface adjacent to the first semiconductor layer and top surface opposite to the bottom surface, the second semiconductor layer having a composition of Alₓ₂Ga₁₋₂As where the stoichiometric parameter x2 is variable with a range of values which are less than or equal to x1 , the second layer being formed such that the stoichiometric parameter x2 decreases substantially monotonically from the bottom surface of the second semiconductor layer to the top surface of the second semiconductor layer; and
(c) forming a third semiconductor layer over the second semiconductor layer and located below the upper face, the third semiconductor layer having a composition of Alₓ₁Ga₁₋₃As where the stoichiometric parameter x3 is substantially constant and substantially less than or equal to the lowest value of the stoichiometric parameter x2 ; and
(d) exposing selected portions of the first, second, and third semiconductor layers to a common etchant to form the ridge such that at least a portion of the first side surface of the ridge has a slope of a forward mesa ridge.

39. The method of claim 38, wherein the second semiconductor layer is formed such that the stoichiometric parameter x2 decreases continuously from the bottom surface of said second semiconductor layer to the top surface of said second semiconductor layer.

40. The method of claim 38, wherein the second semiconductor layer is formed such that the stoichiometric parameter x2 decreases in one or more steps from the bottom surface of said second semiconductor layer to the top surface of said second semiconductor layer.

41. The method of claim 38, wherein the first side face comprises a concave surface.

42. The method of claim 38, wherein the stoichiometric parameter x1 for the first semiconductor layer is in a range of 0.2 to 0.5.

43. The method of claim 38, wherein the stoichiometric parameter x1 for the first semiconductor layer is in a range of 0.25 to 0.35.

44. The method of claim 38, wherein the stoichiometric parameter x1 for the first semiconductor layer is in a range of 0.2 to 0.5, and wherein the stoichiometric parameter x3 for the third semiconductor layer is less than or equal to 0.05.

45. The method of claim 38, wherein said second semiconductor layer has a thickness in a range of 5 nm to 1000 nm.

46. The method of claim 38, wherein said second semiconductor layer has a thickness in a range of 25 nm to 100 nm.

47. The method of claim 38, wherein said second semiconductor layer has a thickness in a range of 25 nm to 35 nm.

48. The method of claim 46, wherein the thickness of said first semiconductor layer is greater than the thickness of said second semiconductor layer, and wherein the thickness of the third semiconductor layer is greater than the thickness of the second semiconductor layer.

49. The method according to claim 38, further comprising a step of forming an electrode layer above said third semiconductor layer and covering at least a portion of the first side of said ridge portion in the longitudinal direction, wherein the thickness of said electrode layer is equal to or more than 100 nm.
